(19) United States
(12) Patent Application Publication
(10) Pub. No.: US 2022/0299869 A1
(43) Pub. Date: Sep. 22, 2022

(54) IMPRINT METHOD AND METHOD OF MANUFACTURING SEMICONDUCTOR DEVICE

(71) Applicant: Kioxia Corporation, Tokyo (JP)

(72) Inventor: Takahiro IWASAKI, Yokkaichi Mie (JP)

(73) Assignee: Kioxia Corporation, Tokyo (JP)

(21) Appl. No.: 17/459,881

(22) Filed: Aug. 27, 2021

(30) Foreign Application Priority Data
Mar. 19, 2021 (JP) 2021-046134

(51) Int. Cl. G03F 7/00; H01L 21/027; H01L 21/324

(52) U.S. Cl. CPC G03F 7/0002; H01L 21/0274; H01L 21/324

(57) ABSTRACT

An imprint method includes acquiring information of a target shot out of a plurality of shots that corresponds to an imprint process and a non-target shot out of the plurality of shots that does not correspond to the imprint process. Based on the information, the imprint method includes determining to perform a first process and a second process for the target shot and the non-target shot, respectively. The first process includes: pressing a template against a resin formed over the substrate; curing the resin by irradiating the resin with light; and releasing the template from the resin. The second process includes irradiating the resin with the light in a state where the template is not pressed against the resin.

### CROSS-REFERENCE TO RELATED APPLICATION

This application is based upon and claims the benefit of priority from Japanese Patent Application No. 2021-046134, filed Mar. 19, 2021, the entire contents of which are incorporated herein by reference.

### FIELD

Embodiments described herein relate generally to an imprint method and a method of manufacturing a semiconductor device.

### BACKGROUND

A manufacturing process of a semiconductor device may include an imprint process. In the imprint process, for example, a template is pressed against a photocurable resin applied on a substrate to transfer a pattern of the template. A plurality of shots are formed on the substrate, and the imprint process is skipped for the shots determined to be defective by a preliminary inspection.

However, the photocurable resin applied on unprocessed defective shots may flow into the shots that are targets of the imprint process and adversely affect the target shot.

### DESCRIPTION OF THE DRAWINGS

FIG. 1 is a view illustrating an example of a configuration of an imprint device according to a first embodiment.

FIG. 2 is a plan view illustrating an example of a wafer obtained in a process of manufacturing a semiconductor device according to the first embodiment.

FIGS. 3A to 3C are cross-sectional views illustrating a process of forming the wafer in the process of manufacturing the semiconductor device according to the first embodiment.

FIGS. 4A to 4D are cross-sectional views illustrating an imprint process performed for the wafer in the process of manufacturing the semiconductor device according to the first embodiment.

FIGS. 5A to 5E are cross-sectional views illustrating a process of processing a process target film in the process of manufacturing the semiconductor device according to the first embodiment.

FIG. 6 is a plan view illustrating an example of the wafer before the imprint process is performed by the imprint device according to the first embodiment.

FIG. 7 is a view illustrating an example of an operation of the imprint process by the imprint device according to the first embodiment.

FIG. 8 is a view illustrating an example of the operation of the imprint process by the imprint device according to the first embodiment.

FIG. 9 is a diagram illustrating an example of the operation of the imprint process by the imprint device according to the first embodiment.

FIG. 10 is a diagram illustrating an example of the operation of the imprint process by the imprint device according to the first embodiment.

FIG. 11 is a diagram illustrating an example of the operation of the imprint process by the imprint device according to the first embodiment.

FIG. 12 is a flowchart illustrating an example of a sequence of the imprint process according to the first embodiment.

FIG. 13 is a view illustrating an observation image of a predetermined target shot acquired by an imprint device according to a second embodiment.

FIG. 14 is a view illustrating an observation image of another target shot acquired by the imprint device according to the second embodiment.

FIG. 15 is a view illustrating an example of an operation of an imprint process by the imprint device according to the second embodiment.

FIG. 16 is a view illustrating an example of the operation of the imprint process by the imprint device according to the second embodiment.

FIG. 17 is a view illustrating an example of the operation of the imprint process by the imprint device according to the second embodiment.

FIG. 18 is a flowchart illustrating an example of a sequence of the imprint process according to the second embodiment.

FIG. 19 is a view illustrating an example of a configuration of a spread scope in an imprint device according to a modification example of the second embodiment.

### DETAILED DESCRIPTION

Embodiments provide an imprint method and a method of manufacturing a semiconductor device capable of reducing an influence of an unprocessed shot on a shot to be processed.

In general, according to one embodiment, an imprint method includes acquiring information of a target shot out of a plurality of shots that corresponds to an imprint process and a non-target shot out of the plurality of shots that does not correspond to the imprint process. Based on the information, the imprint method includes determining to perform a first process and a second process for the target shot and the non-target shot, respectively. The first process includes: pressing a template against a resin formed over the substrate; curing the resin by irradiating the resin with light; and releasing the template from the resin. The second process includes irradiating the resin with the light in a state where the template is not pressed against the resin.

Hereinafter, the present disclosure will be described in detail with reference to the drawings. It is noted that the present disclosure is not limited to the following embodiments. Further, the components of the following embodiments include components that are easily conceived by those skilled in the art or components that are substantially the same.

### First Embodiment

Hereinafter, a first embodiment will be described in detail with reference to the drawings.

Configuration Example of Imprint Device

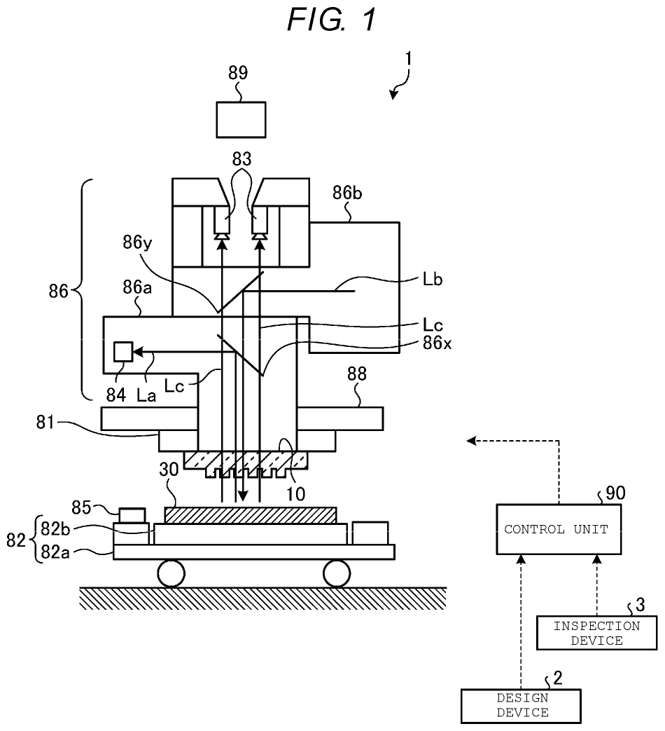

FIG. 1 is a view illustrating an example of a configuration of an imprint device 1 according to the first embodiment. As illustrated in FIG. 1, the imprint device 1 includes a template stage 81, a wafer stage 82, an alignment scope 83, a spread scope 84, a reference mark 85, an alignment portion 86, a stage base 88, a light source 89, and a control unit 90.

Further, the imprint device 1 is installed with a template 10 that transfers a pattern to a resist on a wafer 30 as a substrate. The template 10 is configured with a transparent member such as quartz and is disposed such that pattern faces the wafer stage 82 on which the wafer 30 is placed.

Further, the control unit 90 of the imprint device 1 is connected to a design device 2 and an inspection device 3 which can acquire various types of information.

At the beginning of the manufacturing process of the semiconductor device, the design device 2 performs a design of the semiconductor device and designs layouts of wiring and other configurations of the semiconductor device, a layout of the semiconductor device on a wafer, and the like. The design device 2, transmits, for example, various types of layout information on the wafer 30 that is a target of the imprint process to the control unit 90 of the imprint device 1.

The inspection device 3 performs, for example, a predetermined inspection for the wafer 30 before the imprint process. The inspection device 3 transmits the inspection result of the wafer 30 to the control unit 90 of the imprint device 1. However, a plurality of inspection devices may be connected to the control unit 90 of the imprint device 1.

The wafer stage 82 includes a wafer chuck 82b and a main body 82a. The wafer chuck 82b fixes the wafer 30 to a predetermined position on the main body 82a. The reference mark 85 is provided on the wafer stage 82. The reference mark 85 is used for alignment when the wafer 30 is loaded on the wafer stage 82.

The wafer stage 82 allows the wafer 30 to be placed thereon and moves in a plane (in a horizontal plane) parallel to the placed wafer 30. The wafer stage 82 moves the wafer 30 to a lower side of the template 10 when a transfer process to the wafer 30 is performed.

The stage base 88 supports the template 10 by the template stage 81 and moves the template 10 in an up-and-down direction (vertical direction) to press a pattern of the template 10 against a resist on the wafer 30.

The alignment portion 86 is provided on the stage base 88. The alignment portion 86 detects a position of the wafer 30 and a position of the template 10 based on an alignment mark and the like provided on the wafer 30 and the template 10.

The alignment portion 86 includes a detection system 86a and an illumination system 86b. The illumination system 86b irradiates the wafer 30 and the template 10 with light. The detection system 86a detects images such as the alignment marks provided on the wafer 30 and the template 10 by using the alignment scope 83 and aligns the wafer 30 and the template 10 based on the detection result. Further, the detection system 86a detects whether or not a pattern of the template 10 is filled with a resist by using the spread scope 84 when the template 10 is pressed against the resist of the wafer 30.

The detection system 86a and the illumination system 86b respectively include mirrors 86x and 86y such as dichroic mirrors as image forming units. The mirrors 86x and 86y form images from the wafer 30 and the template 10 by light from the illumination system 86b. Specifically, light Lb from the illumination system 86b is reflected to a lower portion in which the template 10 and the wafer 30 are arranged by the mirror 86y. Light La from the wafer 30 and the template 10 is reflected to the detection system 86a side by the mirror 86x and proceeds to the spread scope 84. Light Lc from the wafer 30 and the template 10 passes through the mirrors 86x and 86y and proceeds to the alignment scope 83 in an upper portion.

The light source 89 emits light capable of curing a resist, such as ultraviolet light, and is provided above the stage base 88. The light source 89 emits light from above the template 10 in a state where the template 10 presses the resist. However, as long as the resist can be cured, the light emitted by the light source 89 may be infrared light other than the ultraviolet light, visible light, an electromagnetic wave, or the like.

The control unit 90 is an information process device that performs various processes for controlling the imprint device 1. The control unit 90 includes, for example, a central processing unit (CPU), a read only memory (ROM), a random access memory (RAM), and the like, and includes a computer that performs a predetermined arithmetic process and a control process according to a program.

The control unit 90 controls the template stage 81, the wafer stage 82, the stage base 88, the light source 89, and the like, which are mechanisms related to the imprint process, based on the observation images acquired by the alignment scope 83, the spread scope 84, and the like. At this time, the control unit 90 refers to the layout information acquired from the design device 2 described above and the inspection result acquired from the inspection device 3 described above.

Method of Manufacturing Semiconductor Device

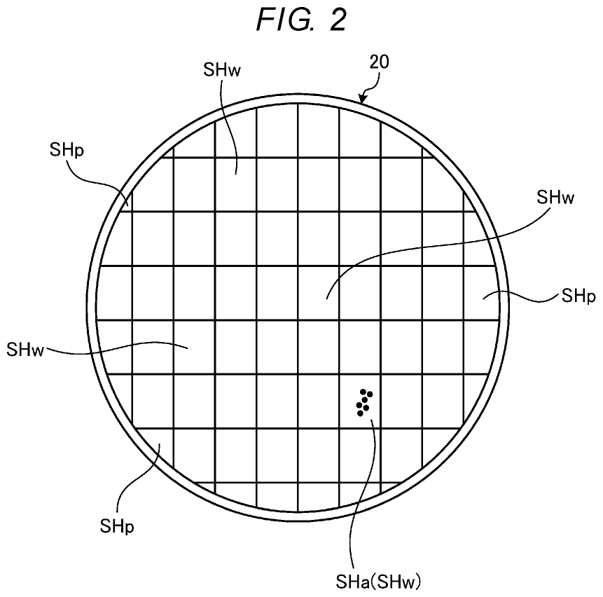

Next, a method of manufacturing a semiconductor device according to the first embodiment will be described with reference to FIG. 2 to FIGS. 5A to 5E. The method of manufacturing the semiconductor device according to the first embodiment includes an imprint process for the wafer 30. First, a process of forming the wafer 30 that is a target of the imprint process will be described.

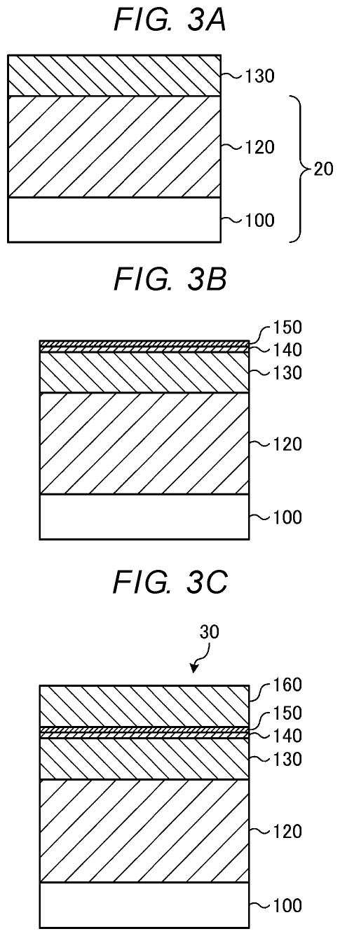

FIG. 2 is a plan view illustrating an example of a wafer 20 obtained in the process of manufacturing the semiconductor device according to the first embodiment. The wafer 20 becomes the wafer 30 that is a target of the imprint process through a process of FIGS. 3A to 3C to be described below.

As illustrated in FIG. 2, the wafer 20 includes a plurality of shots SH (SHw, SHp, and SHa) formed through a plurality of manufacturing processes. The individual shots SH are elements that are units of individual processes of the manufacturing process of the semiconductor device. For example, in the imprint process to be performed below, one shot SH corresponds to each time the template 10 is pressed once.

Among the plurality of shots SH formed on the wafer 20, a normal shot SHw is the shots SH formed in a region other than a peripheral portion of the wafer 20. The normal shot SHw includes all of a predetermined configuration that the shot SH has to include in design, and has, for example, a rectangular shape having a predetermined area. The wafer 20 undergoes a plurality of manufacturing processes to be performed thereafter, and thereby, one or more semiconductor devices can be obtained from one normal shot SHw.

Among the plurality of shots SH formed on the wafer 20, a missing shot SHp is the shot SH formed on the peripheral portion of the wafer 20. Therefore, the missing shot SHp is formed such that a part of the shot SH protrudes from a circumference of the wafer 20 and does not have a part of the predetermined configuration that the shot SH has to include in design. That is, the missing shot SHp has only an area of a predetermined ratio that is less than an area that the shot SH has to have, and a part of the rectangular shape becomes the missing shot SH. Depending on a shape, an area, and the like of the missing shot SHp, the missing shot SHp from which one or more semiconductor devices can be obtained and the missing shot SHp from which no semiconductor device is obtained may exist.

Among the plurality of shots SH formed on the wafer 20, a defective shot SHa is the shot SH in which some defects are generated in the manufacturing process. The defects that can be generated in the manufacturing process include, for example, a case where the number of particles, a contamination level, or the like exceed a predetermined range, or a case where a configuration to be obtained in a predetermined manufacturing process deviates from a specified standard. A defect determination is made based on inspection results performed by various inspection devices after passing through a predetermined manufacturing process. In general, the number of defective shots SHa in one wafer tends to increase as the number of manufacturing processes increases.

It is noted that, in the example of FIG. 2, one of the plurality of normal shots SHw is determined to be defective and becomes the defective shot SHa. However, the missing shot SHp may also be determined to be defective.

FIGS. 3A to 3C are cross-sectional views illustrating a process of forming the wafer 30 in the process of manufacturing the semiconductor device according to the first embodiment. The wafer 30 serving as a substrate is obtained as the wafer 20 passes through a predetermined manufacturing process and is a wafer that is a target of the imprint process, as described above. It is noted that FIGS. 3A to 3C illustrate cross-sectional views of the wafer including a predetermined shot SH.

As illustrated in FIG. 3A, the wafer 20 includes a silicon substrate 100 and a process target film 120 which is formed on the silicon substrate 100. The process target film 120 is a film to be processed by using a stack mask structure to be described below, and is, for example, a single-layer film such as a silicon oxide film or a silicon nitride film, or a stack film in which a plurality of films are stacked.

A spin on carbon (SOC) film 130 is formed on the process target film 120. The SOC film 130 is formed by, for example, a spin coating method, and is an organic film including carbon.

As illustrated in FIG. 3B, a spin on glass (SOG) film 140 is formed on the SOC film 130. The SOG film 140 is formed by, for example, a spin coating method and is an inorganic film such as a silicon oxide film.

An adhesive film 150 is formed on the SOG film 140. The adhesive film 150 is an organic film to which, for example, a surfactant including fluorine atoms or silicon atoms, a silane coupling agent, or the like is added. The adhesive film 150 enhances adhesion between a resist film 160 to be formed thereafter and the SOG film 140.

As illustrated in FIG. 3C, the resist film 160 is formed on the adhesive film 150. A so-called photoresist material, a silicon-containing resist material, or the like may be used as the resist film 160, and the resist film 160 is an example of a photocurable resin formed by, for example, a spin coating method. It is preferable that an imprint material including the photoresist material and the silicon-containing resist material has a viscosity so as to be arrangeable in a film shape on the wafer 20. It is preferable that the viscosity of the imprint material is, for example, 0.1 mPa·s or more. The resist film 160 illustrated in FIG. 3C is a target film of the imprint process to be described below and has a state of a liquid with fluidity until the imprint process is performed.

It is noted that the SOC film 130, the SOG film 140, the adhesive film 150, and the resist film 160 which are formed on the process target film 120 are also referred to as a stack mask structure. By sequentially patterning the respective films while using a difference in etching resistance of each film to different etching gases in the stack mask structure, the process target film 120 can be processed while maintaining a mask structure of a thick film.

The wafer 30 of an imprint process target is formed by the process described above.

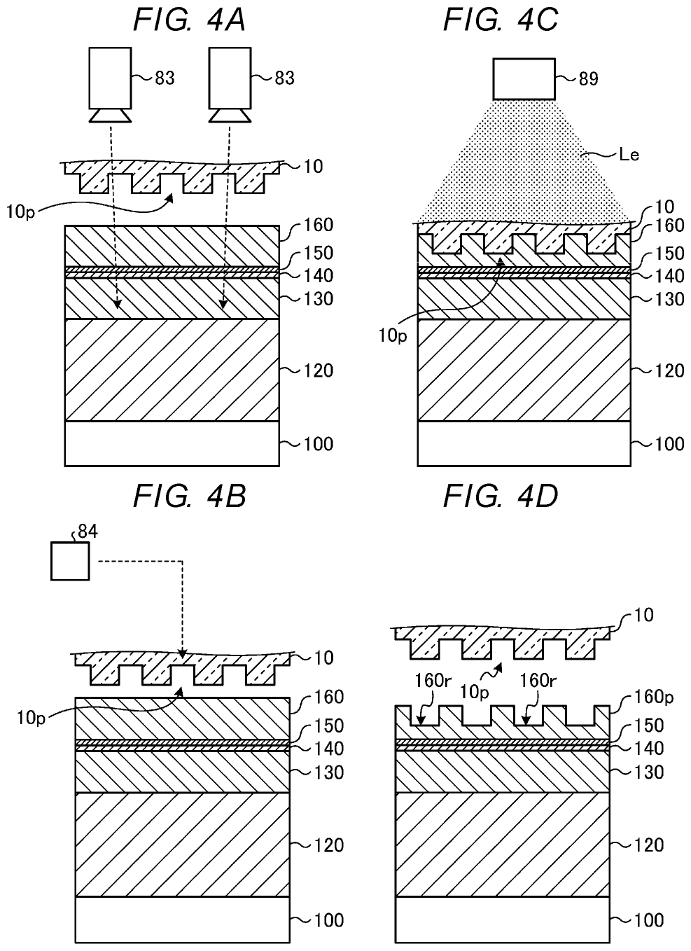

FIGS. 4A to 4D are cross-sectional views illustrating the imprint process performed for the wafer 30 in the process of manufacturing the semiconductor device according to the first embodiment. FIGS. 4A to 4D also illustrate cross-sectional views of the wafer 30 including the predetermined shot SH. It is noted that FIGS. 4A to 4D illustrate only configurations related to each process in the above-described imprint device 1.

Here, among the plurality of shots SH (SHw, SHp, and SHa) described above, some of the missing shots SHp and all or some defective shots SHa do not become a target of the imprint process. It is noted that, since the various manufacturing processes illustrated in FIGS. 3A to 3C described above are performed, the number of defective shots SHa in the wafer 30 may be larger than the number of defective shots in the wafer 20 illustrated in FIG. 2 described above.

As illustrated in FIG. 4A, the wafer 30 is carried into the imprint device 1 and is moved by the wafer stage 82 such that the predetermined shot SH of the wafer 30 is located below the template 10. Thereby, the predetermined shot SH of the wafer 30 and a pattern 10p of the template 10 face each other.

The alignment scope 83 observes an alignment mark (not illustrated) provided on the template 10 and an alignment mark (not illustrated) formed on the wafer 30 from above the template 10 and the wafer 30.

The control unit 90 acquires an observation image from the alignment scope 83. Further, the control unit 90 moves the wafer stage 82 such that the alignment marks of the template 10 and the wafer 30 overlap each other in an up-and-down direction with reference to the observation image. Thereby, a rough alignment is performed for the shot SH of the wafer 30 which are an imprint process target, and the pattern 10p of the template 10. The rough alignment is an operation of roughly aligning positions of the shots SH of the wafer 30 and the pattern 10p of the template 10 before the template 10 is pressed against the resist film 160 of the wafer 30.

As illustrated in FIG. 4B, the control unit 90 lowers the template 10 while observing the template 10 and the wafer 30 by using the spread scope 84 from above the template 10 and the wafer 30.

Thereby, the template 10 is pressed against the resist film 160 of the wafer 30. At this time, in order to reduce a contact between the wafer 30 and the template 10, a lowering position of the template 10 is adjusted such that a projection portion of the pattern 10p of the template 10 is located slightly above a bottom surface of the resist film 160.

When the template 10 comes into contact with the resist film 160 of the wafer 30, the control unit 90 performs a fine alignment of the template 10 and the wafer 30 with reference to the observation image from the spread scope 84. The fine alignment is an operation of precisely aligning positions of the shots SH of the wafer 30 and the pattern 10p of the template 10 in a state where the template 10 is in contact with the resist film 160.

On the other hand, when the template 10 is pressed against the resist film 160 of the wafer 30, the resist film 160 is filled in a recess portion of the pattern 10p so as to follow an uneven portion of the pattern 10p of the template 10.

The control unit 90 performs the fine alignment with reference to the observation image from the spread scope 84, and in some cases, the control unit 90 maintains the state where the template 10 is pressed against the resist film 160 until the recess portion of the pattern 10p of the template 10 is filled with the resist film 160 even after the fine alignment ends.

As illustrated in FIG. 4C, when the resist film 160 is filled in the recess portion of the pattern 10p of the template 10, the light source 89 emits ultraviolet light Le from above the template 10 and the wafer 30 while the state where the template 10 is pressed against the resist film 160 is maintained. The ultraviolet light Le preferably has, for example, any wavelength of 10 nm or more and 400 nm or less. However, as described above, the light which is irradiated may be infrared light other than the ultraviolet light, visible light, an electromagnetic wave, or the like, as long as the light can cure the resist film 160.

The ultraviolet light Le passes through the transparent template 10 to apply on the resist film 160. Thereby, for example, the resist film 160, which is a photocurable resin, is cured to form a patterned resist 160p to which the pattern 10p of the template 10 is transferred.

As illustrated in FIG. 4D, when the template 10 is raised, the template 10 is released from the patterned resist 160p.

The patterned resist 160p has a pattern in which the pattern 10p of the template 10 is inverted. Further, a residual resist film 160r is formed in a recess portion between projection patterns of the patterned resist 160p. This is because, when the template 10 is pressed, the projection portions of the pattern 10p of the template 10 are maintained slightly above a bottom surface of the resist film 160.

Thereby, the imprint process for the wafer 30 ends.

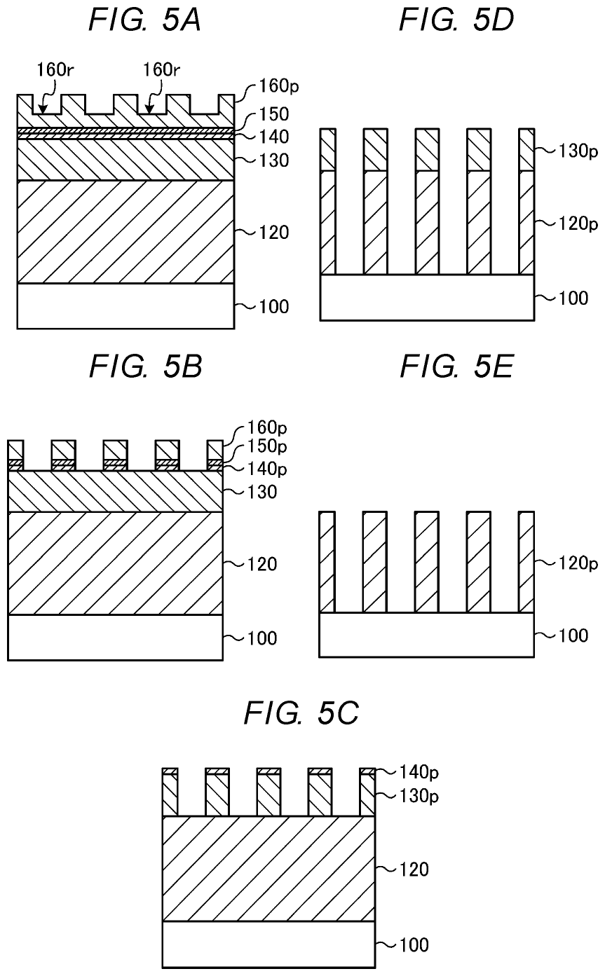

FIGS. 5A to 5E cross-sectional views illustrating a process of processing the process target film 120 in the process of manufacturing the semiconductor device according to the first embodiment. By the process illustrated in FIGS. 5A to 5E, the process target film 120 is processed by using the stack mask structure including the patterned resist 160p, and the patterned resist 160p is transferred to the process target film 120. It is noted that FIGS. 5A to 5E also illustrate cross-sectional views of the wafer 30 including the predetermined shot SH.

As illustrated in FIG. 5A, the patterned resist 160p formed by the imprint process includes the residual resist film 160r between the projection patterns. Further, a rinse process is performed for the patterned resist 160p after the imprint process.

As illustrated in FIG. 5B, the residual resist film 160r and the adhesive film 150 between the projection patterns of the patterned resist 160p are removed through, for example, anisotropic etching using oxygen plasma or the like. The adhesive film 150 becomes a patterned adhesive film 150p. Further, the SOG film 140 is etched by using the patterned resist 160p as a mask to form an SOG pattern 140p.

As illustrated in FIG. 5C, the SOC film 130 is etched by using the SOG pattern 140p as a mask to form an SOC pattern 130p. It is noted that the patterned resist 160p and the adhesive film 150p are organic films similar to the SOC pattern 130p. Thus, in this process, the patterned resist 160p and the adhesive film 150p are lost.

As illustrated in FIG. 5D, the process target film 120 is etched by using the SOC pattern 130p as a mask to form a patterned process target film 120p. Then, the SOG pattern 140p on the SOC pattern 130p is removed. Alternatively, a film thickness of the SOG pattern 140p may be adjusted previously such that the SOG pattern 140p is lost when the process target film 120p is etched.

As illustrated in FIG. 5E, the SOC pattern 130p is removed by asking using oxygen plasma. As described above, the process target film 120p in which a pattern is formed can be obtained.

Thereafter, the semiconductor device according to the first embodiment is manufactured through various manufacturing processes.

Operation Example of Imprint Device

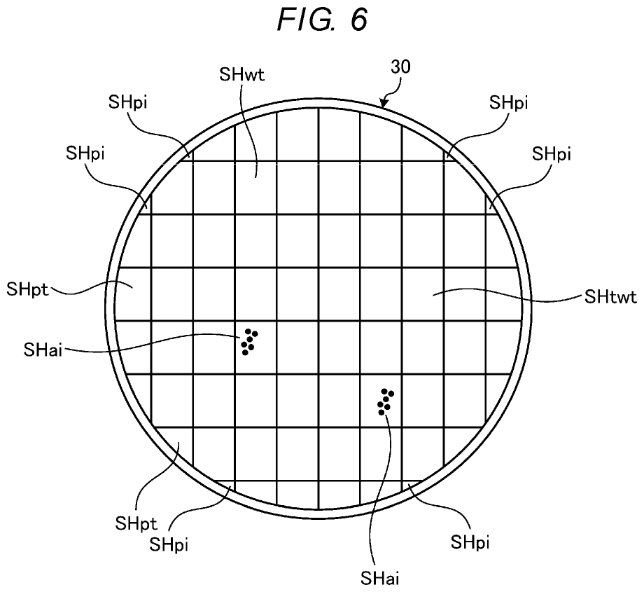

Next, an operation example of the imprint device 1 according to the first embodiment will be described with reference to FIGS. 6 to 11.

FIG. 6 is a plan view illustrating an example of the wafer 30 before the imprint process by the imprint device 1 according to the first embodiment. As illustrated in FIG. 6, the control unit 90 of the imprint device 1 acquires information on non-target shots SHpi and SHai that are not targets of the imprint process from the design device 2 and the inspection device 3 described above, among the plurality of shots SH of the wafer 30, prior to the imprint process for the wafer 30.

As described above, the control unit 90 of the imprint device 1 acquires the layout information on the wafer 30 from the design device 2. The layout information includes information on the non-target shots SHpi that is not the target of the imprint process among the missing shots SHp arranged in the peripheral portion of the wafer 30. The non-target shot SHpi is the shot SH of which a part is missing at a predetermined ratio or more compared to the normal shot SHw arranged in a region other than the peripheral portion of the wafer 30.

That is, among the missing shots SHp, no semiconductor device can be acquired from the missing shot SHp having an area smaller than a predetermined area, and thus, there is no merit in performing the imprint process. Further, when the area of the missing shot SHp is too small, it is difficult to stably press the template 10 to perform the imprint process. Therefore, the missing shot SHp becomes a non-target of the imprint process.

Further, the control unit 90 of the imprint device 1 acquires the inspection result of the wafer 30 from the inspection device 3. The inspection result includes information on the non-target shot SHai that is no longer the target of the imprint process due to a defect determination by the inspection device 3 among the plurality of shots SH of the wafer 30.

For example, when a defect is caused by particles or foreign matters, the imprint process causes the particles or the foreign matters to adhere to the template 10 to contaminate the template, or the template 10 and the wafer 30 and the like are likely to be damaged due to dust entrainment and the like between the template 10 and the wafer 30. Therefore, all or some defective shots SHa become non-targets of the imprint process.

It is noted that, as described above, a plurality of inspection devices may be connected to the control unit 90 of the imprint device 1, and the non-target shot SHai may be information obtained by cumulative results of information provided from the plurality of inspection devices. In the example of FIG. 6, in addition to the defective shots SHa illustrated in FIG. 2, another normal shot SHw is designated as the non-target shot SHai.

As such, the non-target shots SHpi and SHai that do not become targets of the imprint process may include the missing shots SHp having an area smaller than a predetermined area and the defective shots SHa determined to be defective before the imprint process.

The control unit 90 identifies the shots SH other than the non-target shots SHpi and SHai as target shots SHpt and SHwt that are targets of the imprint process, based on the information on the non-target shots SHpi and SHai and the layout information acquired from the design device 2. The target shots SHpt are the shots SH other than the non-target shots SHpi and SHai among the missing shots SHp at the peripheral portion of the wafer 30. The target shots SHwt are the shots SH other than the non-target shots SHai among the normal shots SHw arranged at portions other than the peripheral portion of the wafer 30.

However, the control unit 90 may acquire information of the target shots SHpt and SHwt from the design device 2 and the inspection device 3 together with the information of the non-target shots SHpi and SHai or instead of the information of the non-target shots SHpi and SHai. When the information of the target shots SHpt and SHwt is acquired instead of the information of the non-target shots SHpi and SHai, the control unit 90 identifies the shots SH other than the target shots SHpt and SHwt as the non-target shots SHpi and SHai.

However, in the imprint device 1, a process sequence is predetermined in which the imprint process for the plurality of shots SH in the wafer 30 is performed. The process sequence of the plurality of shots SH is determined such that an efficient process can be performed, for example, the imprint process is sequentially performed for the shots SH close to each other.

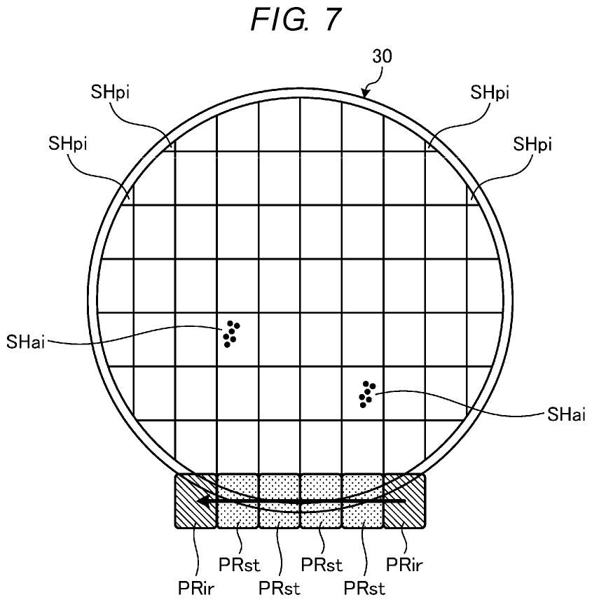

For example, a raster scan method may be used as the process sequence of the plurality of shots SH. In the raster scan method, for example, as illustrated in FIGS. 7 to 11, the imprint process is sequentially performed for the shots SH in one row arranged in a horizontal direction of a drawing sheet, and each time the process for the shots in one row ends, the imprint process is sequentially performed for the shots SH in one row adjacent to each other in a vertical direction of the drawing sheet. As such, by starting the process from a lower end or an upper end of the wafer 30 and ending the process at an opposite end portion, the imprint process can be efficiently performed for the plurality of shots SH.

However, the imprint process may be sequentially performed for the shots SH in one row arranged in the vertical direction of the drawing sheet by using the raster scan method, and each time the process for the shots in one row ends, the imprint process may be sequentially performed for the shots SH in one row adjacent to each other in the horizontal direction of the drawing sheet. As such, by starting the process from the right end or the left end of the wafer 30 and ending the process in an opposite end portion, the imprint process can be efficiently performed for the plurality of shots SH.

FIGS. 7 to 11 illustrate examples of operations of the imprint process by the imprint device 1 according to the first embodiment. Hereinafter, FIGS. 7 to 11 will be described in more detail.

As illustrated in FIG. 7, the control unit 90 of the imprint device 1 moves the wafer stage 82 on which the wafer 30 is placed and sequentially performs a process for the shots SH in one row at the lower end portion of the wafer 30. In the example of FIG. 7, the process proceeds from the shot SH at the right end of the drawing sheet to the shot SH at the left end of the drawing sheet, and the process sequence may be a reverse sequence of proceeding from the left end of the drawing sheet to the right end of the drawing sheet.

The shots SH at the lower end portion of the wafer 30 are all the missing shots SHp, and the non-target shot SHpi, four target shots SHpt, and the non-target shot SHpi are sequentially arranged from the right end. The control unit 90 performs a non-stamping process PRir for the non-target shots SHpi at both ends and performs a stamping process PRst for the four target shots SHpt at the center.

As described above, the stamping process PRst as a first process is a process of pressing the template 10 against the resist film 160, applying ultraviolet light via the template 10 to cure the resist film 160, releasing the template 10 from the resist film 160, and transferring the pattern 10p of the template 10 to the resist film 160. Thereby, the resist film 160 arranged on the target shot SHpt becomes the patterned resist 160p.

The non-stamping process PRir as a second process is a process of irradiating the resist film 160 with ultraviolet light without pressing the template 10 against the resist film 160. At this time, the applying of the ultraviolet light to the resist film 160 may be performed via the template 10 located above the resist film 160 in a state of being in non-contact with the resist film 160. Thereby, the resist film 160 arranged on the non-target shot SHpi is cured without transferring the pattern 10p of the template 10. It is noted that the light to be applied or an electromagnetic wave does not have to be limited to the ultraviolet light. Further, the light to be applied or the electromagnetic wave may not have the same wavelength as in the stamping process PRst.

In the non-stamping process PRir, the resist film 160 may be cured to the same extent as at the time of the above-described stamping process PRst and may not be cured to the same extent. That is, softness of the resist film 160 may be the same as at the time of the stamping process PRst or may be higher than softness at the time of stamping process PRst. That is, a viscosity of the resist film 160 may be higher than a viscosity before the non-stamping process PRir. The non-stamping process PRir is preferably performed in a condition that the viscosity of the resist film 160 after the non-stamping process PRir is, for example, 150 mPa·s or more.

Even in any of the above-described cases, the resist film 160 after ultraviolet light is applied has a higher viscosity than the viscosity before the ultraviolet light is applied, and has substantially no fluidity. In other words, in the non-stamping process PRir, the resist film 160 is cured to an extent that the fluidity of the resist film 160 is substantially lost.

Application conditions such as an application intensity, an application time, and an application wavelength of the ultraviolet light in the non-stamping process PRir may be the same as application conditions in the stamping process PRst and may be different. When the application conditions of the non-stamping process PRir are different, the application conditions may be relaxed such as reducing the application intensity more than the stamping process PRst or reducing the application time.

It should be noted that, in the process of the shots SH at a lower end portion of the wafer 30, a predetermined process sequence is maintained regardless of process content such as the stamping process PRst or the non-stamping process PRir.

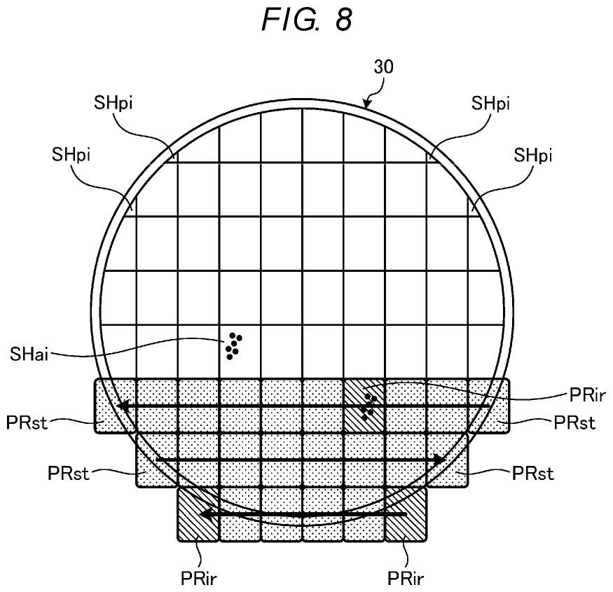

As illustrated in FIG. 8, when the process for all the shots SH at the lower end portion of the wafer 30 ends, the control unit 90 performs a process for the shots SH in one row adjacent to each other in an upward direction of the paper drawing sheet. As in the example of FIG. 7, when the shots SH of the lower end portion of the wafer 30 are processed from the right end toward the left end, the shots SH in a second row from the lower end portion are processed from the left end toward the right end. Since the shots SH in the second row are target shots SHpt and SHwt that are targets of the imprint process, the stamping process PRst is performed for all the shots SH.

When the process for all the shots SH in the second row from the lower end portion of the wafer 30 ends, the control unit 90 executes the process for the shots SH in a third row adjacent to the upward direction of the drawing sheet. In the example of FIG. 8, the process of the shots SH in the second row is performed from the left end to the right end, and thus, a process of the shots SH in the third row is performed from the right end to the left end.

Here, a fourth shot from the right end of the third row is the non-target shot SHai. The control unit 90 sequentially performs the stamping process PRst for three target shots SHpt and SHwt from the right end, and then performs the non-stamping process PRir for the fourth non-target shot SHai without pressing the template 10. Since the fifth and subsequent shots from the right end of the third row are all the target shots SHwt and SHpt, the control unit 90 performs the stamping process PRst for the target shots SHwt and SHpt.

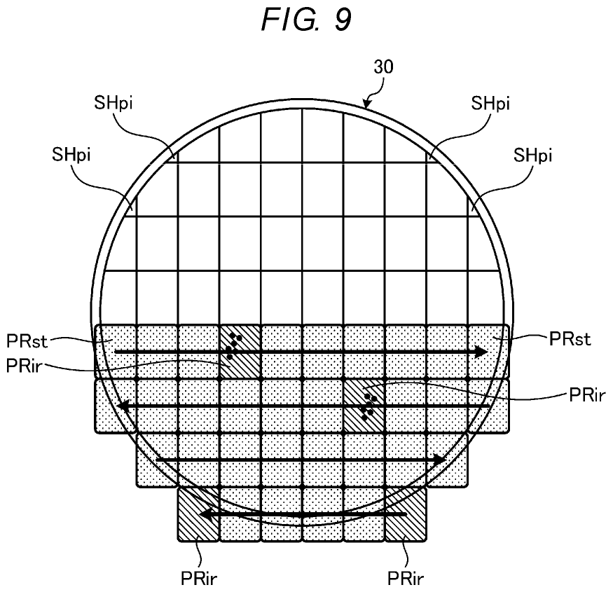

As illustrated in FIG. 9, when the process for all the shots SH in the third row from the lower end portion of the wafer 30 ends, the control unit 90 performs the process for the shots SH in a fourth row adjacent to each other in the upward direction. That is, the control unit 90 sequentially performs the stamping process PRst for the target shots SHpt and SHwt from the left end in an opposite direction to the third row. Then, the control unit 90 performs the non-stamping process PRir for the fourth non-target shot SHai from the left end. Further, the control unit 90 subsequently performs the stamping process PRst for the target shots SHwt and SHpt up to the right end.

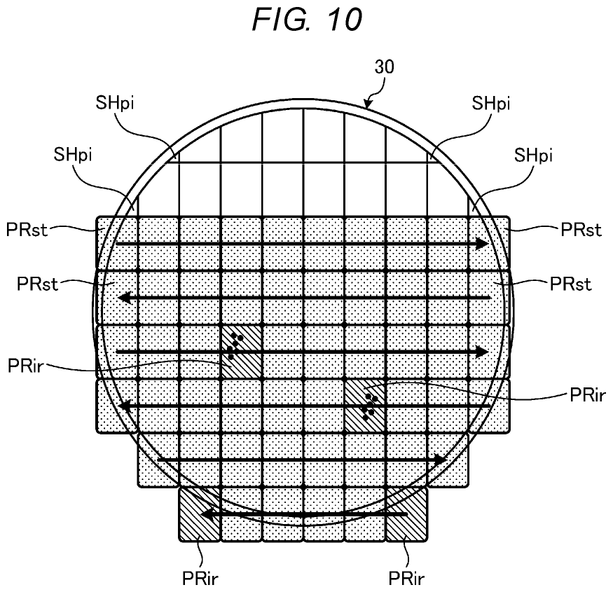

As illustrated in FIG. 10, when the process for all the shots SH in the fourth row from the lower end portion of the wafer 30 ends, the control unit 90 sequentially performs the process for the shots SH in a fifth row and the shots SH in a sixth row adjacent to each other in the upward direction. The shots of the fifth and sixth rows are the target shots SHpt and SHwt. The control unit 90 performs the stamping process PRst for all the target shots SHpt and SHwt in the fifth row from the right end to the left end in an opposite direction to the fourth row. Then, the control unit 90 performs the stamping process PRst for all the target shots SHpt and SHwt in the sixth row from the left end to the right end in an opposite direction to the fifth row.

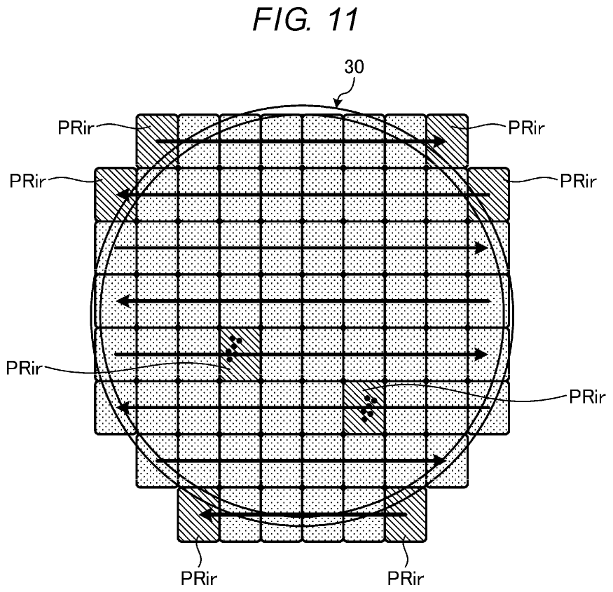

As illustrated in FIG. 11, shots in the left and right end portions of two rows of an upper end portion of the wafer 30 are the non-target shots SHpi, and all the shots in the central portion are the target shots SHwt and SHpt. The control unit 90 performs the non-stamping process PRir for the non-target shot SHpi in the right end of the second row from the upper end portion of the wafer 30, and then, performs the stamping process PRst for the plurality of target shots SHwt and SHpt in the center of the second row, and further performs the non-stamping process PRir for the non-target shot SHpi at the left end of the second row.

Likewise, the control unit 90 performs the non-stamping process PRir for the non-target shot SHpi at the left end of the upper end portion of the wafer 30, and then performs the stamping process PRst for the plurality of target shots SHpt in the center of the upper end portion, and further performs the non-stamping process PRir for the non-target shot SHpi at the right end of the upper end portion.

As described above, one process of the stamping process PRst and the non-stamping process PRir is performed for all the shots SH of the wafer 30.

Example of Imprint Process

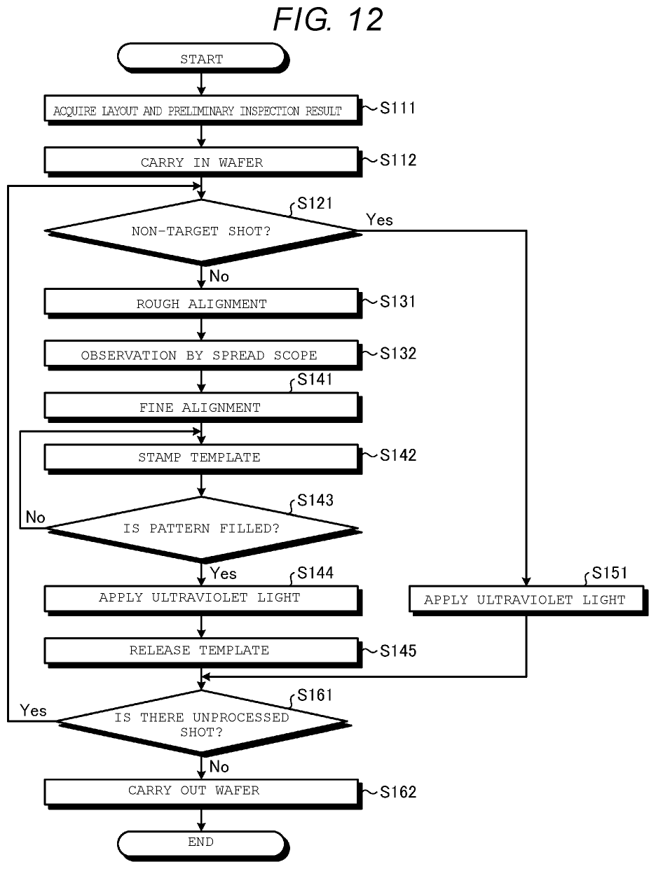

Next, an example of the imprint process by the imprint device 1 according to the first embodiment will be described with reference to FIG. 12. FIG. 12 is a flowchart illustrating an example of a sequence of the imprint process according to the first embodiment.

As illustrated in FIG. 12, in an imprint method according to the first embodiment, the wafer 30 is processed in which the plurality of shots SH are coated with the resist film 160.

That is, the control unit 90 of the imprint device 1 previously acquires a layout and a preliminary inspection result of the wafer 30 that is a target of the imprint process from each of the design device 2 and the inspection device 3 (step S111).

The control unit 90 carries the wafer 30 of which the layout and the preliminary inspection result are acquired into the imprint device 1 by using a conveyance mechanism (not illustrated) or the like (step S112).

However, the process of step S111 may be performed before a process for the first shot SH of the plurality of shots SH of the wafer 30 starts, for example, a process sequence of step S111 and step S112 may be reversed.

Thereafter, the process for the plurality of shots SH of the wafer 30 is performed according to a previously determined process sequence. At that time, the control unit 90 appropriately drives the wafer stage 82 such that the shots SH to be processed are arranged at a lower position of the template 10.

When the predetermined shot SH is arranged at the lower position of the template 10 among the plurality of shots SH of the wafer 30, the control unit 90 determines whether or not the shot SH corresponds to any of the non-target shots SHpi and SHai based on information acquired from the design device 2 and the inspection device 3 (step S121).

When the above-described shot SH does not correspond to any of the non-target shots SHpi and SHai, that is, when the above-described shot SH is any of the target shots SHpt and SHwt (step S121: No), the control unit 90 performs the process of steps S131, S132, and S141 to S145.

That is, the control unit 90 performs a rough alignment between the template 10 and the shot SH of the wafer 30 based on an observation image from the alignment scope 83 (step S131). When the rough alignment ends, the control unit 90 lowers the template stage 81 with reference to the observation image from the spread scope 84 (step S132) and brings the template 10 into contact with the resist film 160 of the shot SH arranged at the lower position of the template 10 to perform a fine alignment (step S141).

The control unit 90 stops the template 10 at a stamping position where the pattern 10p can be transferred to the resist film 160 (step S142). Then, the control unit 90 subsequently determines whether or not the pattern 10p of the template 10 is filled with the resist film 160 with reference to the observation image from the spread scope 84 (step S143). When there is an unfilled portion in the pattern 10p (step S143: No), the template 10 is continuously stamped (step S142).

It is noted that at least a part of the process from step S141 to step S143 may be performed in parallel.

When there is no unfilled portion of the pattern 10p (step S143: Yes), ultraviolet light from the light source 89 is applied to the resist film 160 of the shot SH being stamped via the template 10 (step S144).

After the ultraviolet light is applied, the control unit 90 raises the template stage 81 and releases the template 10 from the patterned resist 160p to which the pattern 10p of the template 10 is transferred (step S145).

On the other hand, when the shot SH corresponds to any of the non-target shots SHpi and SHai (step S121: Yes), the control unit 90 applies the ultraviolet light from the light source 89 to the resist film 160 of the shot SH arranged at the lower position of the template 10 via the template 10 without being in contact with the template 10 (step S151).

However, the control unit 90 may perform the same rough alignment process as in step S131 before performing the process of step S151. Thereby, an application region by the light source 89 is likely to be limited to the shot SH at the lower position of the template 10, and even the shots SH around the shot SH can be prevented from being cured.

When either the stamping process PRst or the non-stamping process PRir for the shot SH at the lower position of the template 10 ends, the control unit 90 determines whether or not there is an unprocessed shot SH for which any of the stamping process PRst and the non-stamping process PRir is not performed (step S161).

When there is the unprocessed shot SH (step S161: Yes), the control unit 90 repeats the process for the unprocessed shot SH from step S121. When the process for all the shots SH is completed (step S161: No), the control unit 90 carries the wafer 30 having all the processed shots SH to the outside of the imprint device 1 by using a conveyance mechanism (not illustrated) or the like (step S162).

As described above, the imprint process by the imprint device 1 according to the first embodiment ends.

Overview

When an imprint process is performed, an imprint material such as a resist is disposed on a wafer by, for example, an inkjet method. In the inkjet method, for example, droplets of the imprint material are dropped for each shot immediately before a template is stamped. In the imprint process, by pressing the template against a droplet-shaped imprint material, the imprint material spreads like a film over all shots, and a patterned resist covering all the shots can be formed.

On the other hand, a spin coating method is studied as a method for arranging an imprint material on a wafer. In the spin coating method, a spin coating device or the like is used to rotate the wafer held on a rotation support base in the spin coating device at high speed to drop the imprint material onto the wafer. The imprint material is applied to the entire wafer by a centrifugal force to form a film of the imprint material such as a resist film covering the entire surface of the wafer. By applying the imprint material by using the spin coating method, a time waiting for the imprint material to spread for each shot is reduced, and thus, throughput of the imprint process can be increased.

However, there are also a problem in the spin coating method. For example, in the imprint process, a process of a defective shot and some missing shots is skipped sometimes. The resist film arranged on the shot for which the process is skipped remains uncured and has fluidity. Therefore, when a predetermined time elapses, the uncured resist may flow from an unprocessed shot to a processed shot. Thereby, a patterned resist formed on the processed shot may be damaged, and a yield of a semiconductor device may be reduced.

According to the imprint process of the first embodiment, while maintaining a previously determined process sequence for the plurality of shots SH, it is determined to perform the stamping process PRst for the target shots SHpt and SHwt and to perform the non-stamping process PRir for the non-target shots SHpi and SHai. Thereby, the resist film 160 of the non-target shots SHpi and SHai can be prevented from flowing into the target shots SHpt and SHwt and an influence of the unprocessed shot SH on the shot SH to be processed can be reduced.

According to the imprint process of the first embodiment, information of at least any of the target shots SHpt and SHwt that are targets of the imprint process and the non-target shots SHpi and SHai that are not the targets of the imprint process among the plurality of shots SH is acquired.

As such, by acquiring layout information and setting the missing shot SHp, which is partially missed more than the normal shot SHw at a predetermined ratio or more, as the non-target shot SHpi, unnecessary stamping process can be reduced to increase throughput and unstable stamping process for the missing shot SHp having a small area can be prevented from being performed.

Further, as described above, by acquiring an inspection result and setting the defective shot SHa determined to be defective by a preliminary inspection as the non-target shot SHai, unnecessary stamping process can be reduced to increase throughput, and further, for example, the template 10 can be prevented from being contaminated by particles or foreign matters of the defective shot SHa, or the template 10 and the wafer 30 can be prevented from being damaged.

According to the imprint process of the first embodiment, a process sequence is determined to sequentially perform the processes for the shots SH adjacent to each other among the plurality of shots SH. Thereby, the imprint process can be efficiently performed and further, the resist film 160 can be prevented from flowing into because the non-target shots SHpi and SHai remain unprocessed for a long time.

### Second Embodiment

Hereinafter, a second embodiment will be described with reference to the drawings. An imprint process according to the second embodiment is different from the imprint process according to the first embodiment described above in that a defective shot is also determined during the imprint process.

It is noted that the imprint process according to the second embodiment can be performed by a control unit in an imprint device according to the second embodiment, for example, by controlling each configuration which is the same as the imprint device 1 according to the first embodiment described above. Thus, in the following, each unit except the control unit in the imprint device according to the second embodiment will be described by using the same reference numerals as the reference numerals of the imprint device 1 of FIG. 1 described above.

Operation Example of Imprint Device

The control unit of the imprint device according to the second embodiment acquires observation images of appearances of the target shots SHpt and SHwt when the stamping process for the individual target shots SHpt and SHwt is performed. The appearances of the target shots SHpt and SHwt are observed by, for example, the spread scope 84. Then, the control unit according to the second embodiment determines whether or not the individual target shots SHpt and SHwt have defects, from the observed appearances.

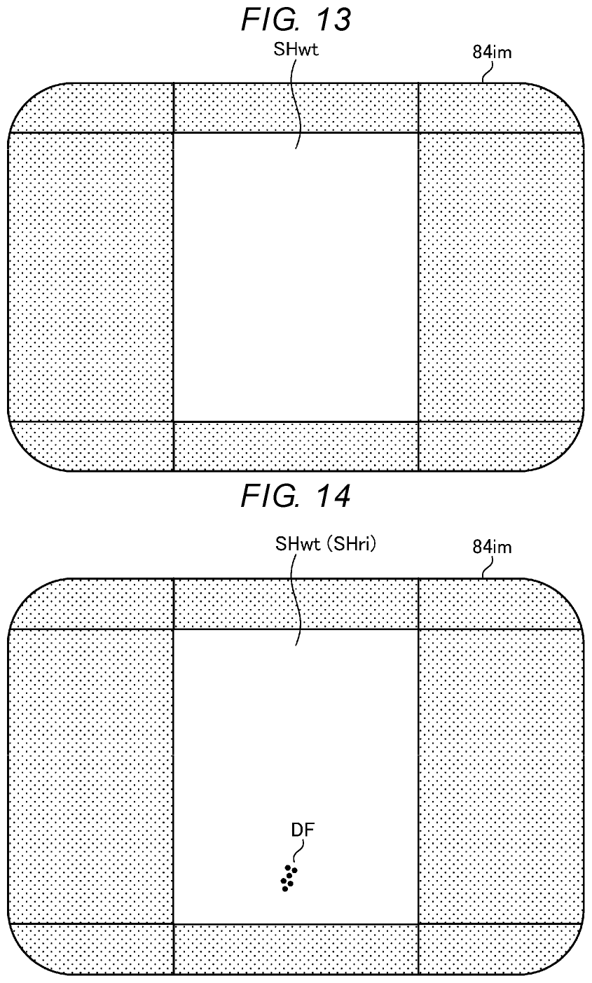

FIG. 13 is a view illustrating an observation image 84im of the predetermined target shot SHwt acquired by the imprint device according to the second embodiment. No defect is found in appearance in the target shot SHwt illustrated in FIG. 13. In this case, the control unit according to the second embodiment sets the target shot SHwt as a target of the imprint process as it is and performs the stamping process PRst for the target shot SHwt as originally planned.

It is noted that, even when the shot SH having no defect found in appearance is the missing target shot SHpt, the control unit according to the second embodiment sets the shot SH as a target of the imprint process as it is, and the stamping process PRst is performed for the target shot SHpt as originally planned.

FIG. 14 is a view illustrating an observation image 84im of another target shot SHwt acquired by the imprint device according to the second embodiment. Defects DF are found in appearance in the target shot SHwt illustrated in FIG. 14. It is noted that the defects DF herein may be various defects that can be identified from the appearance, such as particles, foreign matters, and shape abnormality.

In this case, the control unit according to the second embodiment does not set the target shot SHwt as the target of the imprint process and performs the non-stamping process PRir for the target shot SHwt instead of the stamping process PRst.

It is noted that, even when the shot SH having defect found in appearance is the missing target shot SHpt, the control unit according to the second embodiment does not set the shot SH as a target of the imprint process and performs the non-stamping process PRir for the target shot SHpt instead of the stamping process PRst.

In other words, the control unit according to the second embodiment designates the target shots SHpt and SHwt having defects found in appearance as a non-target shot SHri, and performs the non-stamping process PRir for the newly designated non-target shot SHri, in the same manner as the shots SH previously designated as the non-target shots SHpi and SHai.

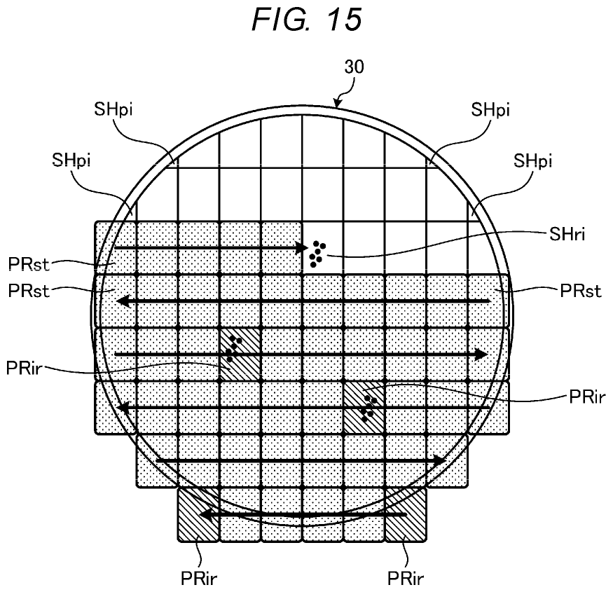

FIGS. 15 to 17 are views illustrating examples of an operation of the imprint process by the imprint device according to the second embodiment. In the wafers 30 illustrated in FIGS. 15 to 17, it is assumed that the target shots SHpt and SHwt and the non-target shots SHpi and SHai have the same arrangement as the wafer 30 of FIG. 6 described above.

As illustrated in FIG. 15, the imprint process according to the second embodiment proceeds for the wafer 30 in the same manner as the process of the example according to the first embodiment described above. However, in the imprint process according to the second embodiment, observation images of appearances of the individual target shots SHpt and SHwt are acquired before the process is performed therefor. Further, it is determined whether or not the target shots SHpt and SHwt have defects, based on the appearances of the individual target shots SHpt and SHwt.

Here, it is assumed that, during the process of the shots SH in the third row from an upper end portion of the wafer 30, a defect is found in appearance in a sixth target shot SHwt from the left end. In this case, the control unit according to the second embodiment designates the target shot SHwt as the non-target shot SHri.

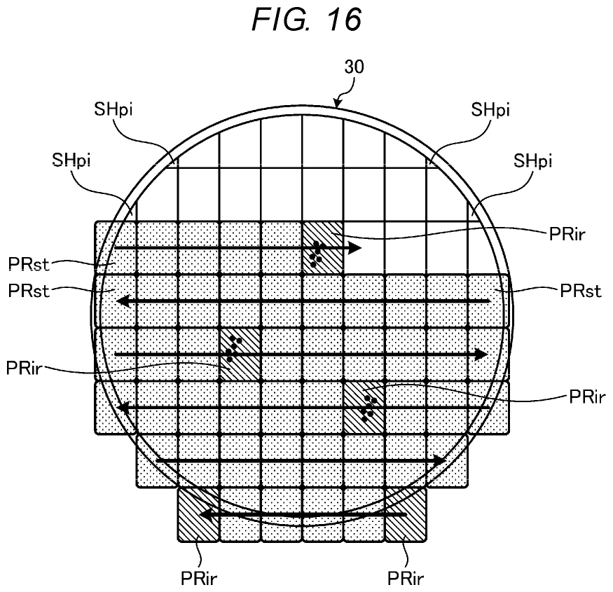

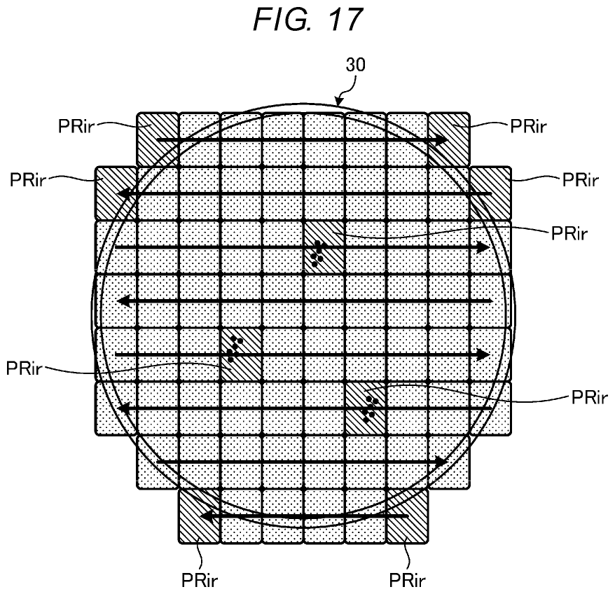

As illustrated in FIG. 16, the control unit according to the second embodiment performs the non-stamping process PRir for the non-target shot SHri described above.

As illustrated in FIG. 17, the control unit according to the second embodiment performs either the stamping process PRst or the non-stamping process PRir for the remaining shots SH while determining whether or not the target shots SHpt and SHwt have defects based on the appearances of the individual target shots SHpt and SHwt even thereafter.

As described above, one process of the stamping process PRst and the non-stamping process PRir is performed for all the shots SH of the wafer 30.

Example of Imprint Process

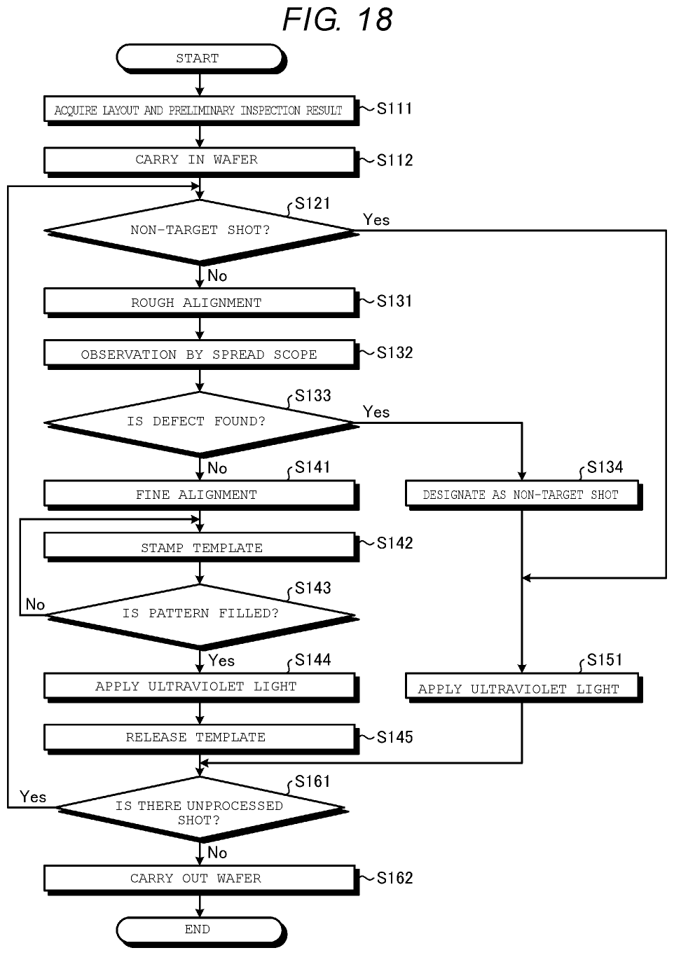

Next, an example of the imprint process by the imprint device according to the second embodiment will be described with reference to FIG. 18. FIG. 18 is a flowchart illustrating an example of a sequence of the imprint process according to the second embodiment.

As illustrated in FIG. 18, the process from step S111 to step S132 is the same as the process from steps S111 to step S132 of FIG. 12 described above.

That is, the control unit according to the second embodiment observes appearances of the target shots SHpt and SHwt for each of a plurality of target shots SHpt and SHwt when performing the imprint process for the plurality of target shots SHpt and SHwt while maintaining a previously determined process sequence (step S132).

The control unit according to the second embodiment determines whether or not the target shots SHpt and SHwt have defects from the appearances of the observed target shots SHpt and SHwt (step S133). It is noted that pass/fail determination based on the appearances is performed for the target shots SHpt and SHwt arranged at a lower position of the template 10 with reference to the observation images from the spread scope 84.

When in the target shots SHpt and SHwt have no defect (step S133: No), the control unit according to the second embodiment performs the process of step S141 to step S145 for the target shots SHpt and SHwt in the same manner as in FIG. 12 described above.

However, a rough alignment process of step S131 may be performed after it is determined by the process of step S132 and step S133 that no defect is found in the target shots SHpt and SHwt.

When the target shots SHpt and SHwt have defects (step S133: Yes), the control unit according to the second embodiment designates the target shots SHpt and SHwt having the defects as the non-target shots SHri (step S134). Further, the control unit according to the second embodiment performs the process of step S151 for the non-target shots SHri in the same manner as in FIG. 12 described above.

Further, even when the shot SH arranged at the lower position of the template 10 corresponds to any of the non-target shots SHpi and SHai (step S121: Yes), the control unit according to the second embodiment performs the process of step S151 for the non-target shots SHpi and SHai in the same manner as in FIG. 12 described above.

It is noted that the control unit according to the second embodiment may perform the same rough alignment process as in step S131 before performing the process of step S151 for the non-target shots SHri, SHpi, and SHai.

When either the stamping process PRst or the non-stamping process PRir for the shots SH at the lower position of the template 10 ends, the process of step S161 is performed in the same manner as in FIG. 12 described above, and then, the process from step S121 is repeated, or the process of step S162 is performed.

As described above, the imprint process by the imprint device according to the second embodiment ends.

According to the imprint process of the second embodiment, the same effect as the imprint process according to the first embodiment described above is obtained.

According to the imprint process of the second embodiment, determination to perform the stamping process PRst for the target shots SHpt and SHwt determined to have no defect is maintained, and the non-stamping process PRir is determined to perform again for the target shots SHpt and SHwt determined to have defects.

Thereby, whether or not to perform the imprint process can be determined based on not only the preliminary inspection result before the imprint process but also a state of the shot SH in real time. Thus, unnecessary stamping process can be further reduced and throughput can be further increased. Further, contamination of the template 10 and damage to the template 10 and the wafer 30 can be further reduced.

### Modification Example

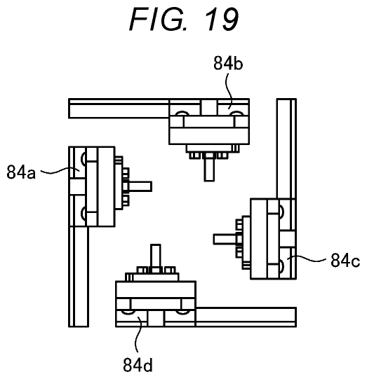

Next, an imprint process according to a modification example of the second embodiment will be described with reference to FIG. 19. The imprint process according to the modification example differs from the imprint process according to the second embodiment in that a pass/fail determination for the next shot SH is performed in parallel with the stamping process PRst or the non-stamping process PRir for a predetermined shot SH.

As described above, an imprint device according to the modification example includes, for example, a plurality of spread scopes 84a to 84d as illustrated in FIG. 19 such that the stamping process PRst or the non-stamping process PRir for the predetermined shot SH and the pass/fail determination for the next shot SH can be performed in parallel.

FIG. 19 is a view illustrating an example of a configuration of the spread scopes 84a to 84d in the imprint device according to the modification example of the second embodiment. As illustrated in FIG. 19, the spread scopes 84a to 84d are arranged to face a lower position in a substantially central direction of a predetermined region to surround the predetermined region. However, regardless of the example of FIG. 19, the number of spread scopes according to the modification example may be 2, 3, 5 or more.

With the configuration, the imprint device according to the modification example performs a pass/fail determination for the next target shots SHpt and SHwt in parallel with the stamping process PRst for the predetermined target shots SHpt and SHwt.

That is, at least one of the spread scopes 84a to 84d captures an observation image including the target shots SHpt and SHwt for which a fine alignment process and the stamping process PRst are in progress. The control unit according to the modification example determines, from the observation image, a status of the fine alignment process of the template 10 for the target shots SHpt and SHwt, and a status of filling the resist film 160 into the pattern 10p of the template 10 during stamping.

On the other hand, at least another one of the spread scopes 84a to 84d captures an observation image including the target shots SHpt and SHwt next to the target shots SHpt and SHwt for which the fine alignment process and the stamping process PRst are in progress. The control unit according to the modification example determines, from the observation image, appearances of the next target shots SHpt and SHwt, and determines whether or not there is a defect.

Further, the imprint device according to the modification example performs a pass/fail determination for the next target shots SHpt and SHwt in parallel with the non-stamping process PRir for the predetermined non-target shots SHpi, SHai, and SHri.

In this case, the spread scopes 84a to 84d for capturing the non-target shots SHpi, SHai, and SHri for which the non-stamping process PRir is in progress are unnecessary.

On the other hand, at least one of the spread scopes 84a to 84d, captures an observation image including the target shots SHpt and SHwt next to the non-target shots SHpi, SHai, and SHri for which the non-stamping process PRir is in progress. The control unit according to the modification example determines, from the observation image, appearances of the next target shots SHpt and SHwt, and determines whether or not there is a defect.

It is noted that a pass/fail determination for the next target shots SHpt and SHwt preferably ends until the stamping process PRst for the predetermined target shots SHpt and SHwt or the non-stamping process PRir for the predetermined non-target shots SHpi, SHai, and SHri ends. Thereby, a process for the next target shots SHpt and SHwt can promptly start.

According to the imprint process of the modification example, the stamping process PRst or the non-stamping process PRir for the predetermined shot SH and a pass/fail determination for the next shot SH are performed in parallel. Thereby, throughput of the imprint process is further increased.

### Other Embodiments

In the first and second embodiments and the modification example described above, the control unit of the imprint device previously acquires information on the non-target shots SHpi and SHai. However, the control unit of the imprint device may determine the non-target shots SHpi and SHai based on the layout information acquired by the design device 2 and the inspection result acquired by the inspection device 3.

In the first and second embodiments and the modification example described above, the imprint process by the imprint device is used for manufacturing a semiconductor device. The imprint process may also be used in manufacturing an electronic device such as a microelectromechanical system (MEMS) or a magnetic recording device, a magnetic recording medium, and the like. Further, in the imprint process, a plurality of patterned resists having different film thicknesses can be formed on one resist film. Thus, the imprint process may be used to form a structure having a step difference of a stair shape and a structure of a lens shape.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. An imprint method of processing a substrate, comprising:
acquiring information of a target shot out of a plurality of shots that corresponds to an imprint process and a non-target shot out of the plurality of shots that does not correspond to the imprint process; and
based on the information, determining to perform a first process and a second process for the target shot and the non-target shot, respectively, wherein
the first process includes:
pressing a template against a resin formed over the substrate;
curing the resin by irradiating the resin with light; and
releasing the template from the resin, and
the second process includes irradiating the resin with the light in a state where the template is not pressed against the resin.

2. The imprint method according to claim 1, wherein the non-target shot includes at least one of:
a missing shot disposed in a peripheral portion of the substrate and having a reduced area than a normal shot, or
a defective shot determined through a preliminary inspection.

3. The imprint method according to claim 1, further comprising:
when performing the imprint process for a plurality of target shots, observing an appearance of each of the target shots, determining whether or not the target shots have a defect based on the observed appearances, and
if the target shots are determined to have a defect, then maintaining to perform the first process for the target shots, or
if the target shots are determined to have a defect, performing the second process for the target shots.

4. The imprint method according to claim 1, further comprising sequentially performing either the first process or the second process for adjacent shots among the plurality of shots.

5. A method of manufacturing a semiconductor device, which includes an imprint process of a substrate including a plurality of shots coated with a resin, comprising:
acquiring information of a target shot that corresponds to the imprint process and a non-target shot that does not correspond to the imprint process; and
based on the information, determining to perform a first process for the target shot and a second process for the non-target shot, wherein
the first process includes:
pressing a template against a resin formed over the substrate;
curing the resin by irradiating the resin with light; and
releasing the template from the resin, and
the second process includes irradiating the resin with the light in a state where the template is not pressed against the resin.

6. The imprint method according to claim 1, wherein the light includes one of: ultraviolet light, infrared light, or visible light.

7. The imprint method according to claim 1, wherein the resin includes a photoresist material.

8. The imprint method according to claim 1, wherein the first process further includes transferring the pattern on the resin to the substrate.

9. The imprint method according to claim 1, wherein, prior to curing the resin by irradiating the resin with light, the first process further includes determining that no unfilled portion is present between the template and the resin.

10. The method according to claim 5, wherein the light includes one of: ultraviolet light, infrared light, or visible light

11. The method according to claim 5, wherein the resin includes a photoresist material.

12. The method according to claim 5, wherein the first process further includes transferring the pattern on the resin to the substrate.

13. The method according to claim 5, wherein, prior to curing the resin by irradiating the resin with light, the first process further includes determining that no unfilled portion is present between the template and the resin.

14. The method according to claim 5, wherein a plurality of processes are carried out, each of the plurality of processes being the first process or the second process.
